(19) United States
(12) Patent Application Publication
(10) Pub. No.: US 2026/0082914 A1
(43) Pub. Date: Mar. 19, 2026

(54) COOLER AND COOLING SYSTEM

(71) Applicant: Mitsubishi Electric Mobility Corporation, Tokyo (JP)

(72) Inventors: Yugo ASAI, Tokyo (JP); Hiroyuki USHIFUSA, Tokyo (JP)

(73) Assignee: Mitsubishi Electric Mobility Corporation, Tokyo (JP)

(21) Appl. No.: 19/110,924

(22) PCT Filed: Oct. 17, 2022
(86) PCT No.: PCT/JP2022/038625

§ 371 Date: Mar. 12, 2025

(51) Int. Cl. H10W 40/47

(52) U.S. Cl. CPC H10W 40/47

(57) ABSTRACT

A cooler is for cooling a heat generation body. The cooler includes: a case having an outer surface on which the heat generation body is provided, the case having an internal space in which a coolant flows; and fins protruding from an inner surface of the case and forming a coolant flow path in the internal space. The fins have: a plurality of pillar-shaped portions arranged in a staggered pattern; a plurality of plate-shaped portions each of which is orthogonal to a height direction H of the case and mutually connects the corresponding pillar-shaped portions that are adjacent to each other in a flow direction F in which the coolant flows; and a plurality of oblique connection portions each of which mutually connects the corresponding pillar-shaped portions that are adjacent to each other in an oblique direction obliquely intersecting with the flow direction F.

### TECHNICAL FIELD

The present disclosure relates to a cooler and a cooling system.

### BACKGROUND ART

Vehicles such as electric automobiles need to have, in order to drive motors thereof, power conversion devices such as switching power supplies, inverters, or converters.

Each of the power conversion devices includes, for example, semiconductor elements such as metal-oxide-semiconductor field-effect transistors (MOSFETs) or insulated-gate bipolar transistors (IGBTs). Such a power conversion device handles large current and generates heat so as to have a high temperature. Therefore, a liquid-cooling-type cooler is generally used for cooling the power conversion device.

This type of cooler (referred to as “conventional cooler” below) is in the form of a box, and a cooling liquid flows inside the cooler. A power conversion device is attached to the external surface of one plate (referred to as “heat dissipation plate” below) forming the box as a form of the cooler. Consequently, heat from the power conversion device is transmitted via the heat dissipation plate to the cooling liquid flowing inside the cooler, whereby the power conversion device is cooled. Furthermore, as in Patent Document 1, the internal surface (i.e., the surface with which the cooling liquid comes into contact) of the heat dissipation plate is provided with pin fins at intervals in order to improve the cooling efficiency of the heat dissipation plate.

### CITATION LIST

PATENT DOCUMENT

Patent Document 1: WO2012/157247

### SUMMARY OF THE INVENTION

### Problem to be Solved by the Invention

Such pin fins are used in the conventional cooler in many cases. Since the pin fins are provided at intervals, a distribution is formed in relation to the flow rates between the fins, the surface areas of the pin fins cannot be effectively utilized, and the heat transfer coefficient is decreased. In addition, the pin fins sustain increase in the distribution of the flow rates owing to influence of peeling, and this increase leads to further decrease in the heat transfer coefficient. Thus, the conventional cooler has a problem in that the cooling efficiency is poor.

The present disclosure has been made to solve the above problems, and an object of the present disclosure is to provide a cooler and a cooling system for efficiently cooling heat generated from a heat generation body.

### MEANS TO SOLVE THE PROBLEM

A cooler according to the present disclosure is a cooler for cooling a heat generation body, the cooler including: a case having an outer surface on which the heat generation body is provided, the case having an internal space in which a coolant flows; and fins protruding from an inner surface of the case and forming a coolant flow path in the internal space. The fins have: a plurality of pillar-shaped portions arranged in a staggered pattern; a plurality of plate-shaped portions each of which is orthogonal to a height direction of the case and mutually connects the corresponding pillar-shaped portions that are adjacent to each other in a flow direction in which the coolant flows; and a plurality of oblique connection portions each of which mutually connects the corresponding pillar-shaped portions that are adjacent to each other in an oblique direction obliquely intersecting with the flow direction.

A cooling system according to the present disclosure is a cooling circuit through which a coolant flows, the cooling system including: the cooler according to the present disclosure; a heat exchanger which cools the coolant; a pump which sends the coolant to the cooler; and piping connecting the cooler, the heat exchanger, and the pump.

### EFFECT OF THE INVENTION

The present disclosure makes it possible to efficiently cool heat generated from a heat generation body.

### BRIEF DESCRIPTION OF THE DRAWINGS

FIG. 1 is a perspective view of a cooler according to embodiment 1.

FIG. 2 is a schematic configuration diagram of the cooler according to embodiment 1.

FIG. 3 is a cross-sectional view showing a cross section taken along A-A in FIG. 1.

FIG. 4 is a plan view of a main surface of a heat dissipation plate according to embodiment 1 as seen in a direction orthogonal to the main surface.

FIG. 5 is a cross-sectional view showing a cross section taken along B-B in FIG. 4.

FIG. 6 is a cross-sectional view showing a cross section taken along C-C in FIG. 4.

FIG. 7 is a schematic diagram of arrangement of fins according to embodiment 1.

FIG. 8 is a plan view of a heat dissipation plate to be compared with the heat dissipation plate in embodiment 1.

FIG. 9 is a schematic configuration diagram of a cooler according to embodiment 2.

FIG. 10 is a configuration diagram of a cooling system according to embodiment 3.

### DESCRIPTION OF EMBODIMENTS

Hereinafter, embodiments of the present disclosure will be described with reference to the drawings. In the drawings, the same or corresponding constituents are denoted by the same reference characters, and this denotation applies to the entire text of the specification. The constituents described in the entire text of the specification are merely examples, and no limitation to the described constituents is made.

### Embodiment 1

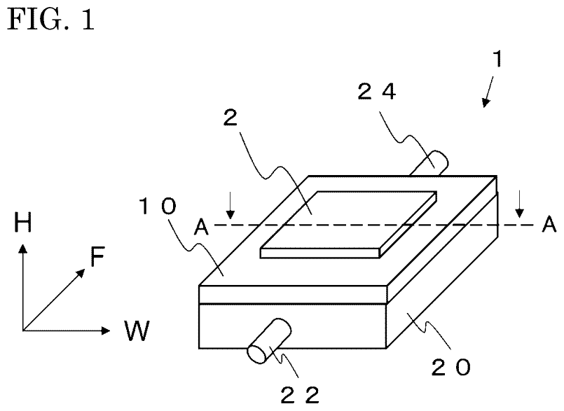

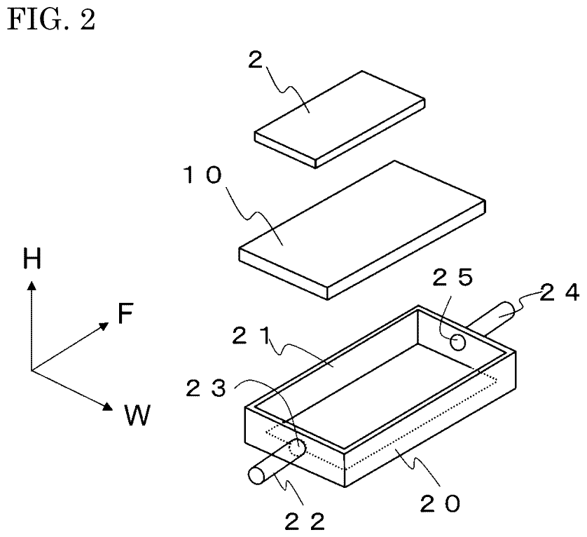

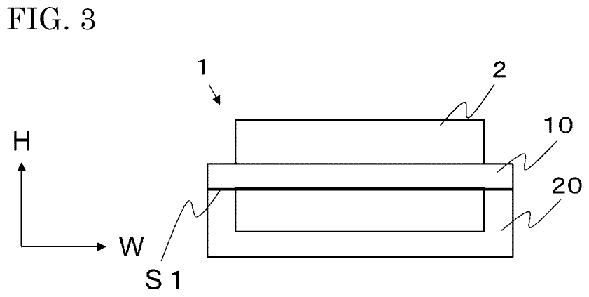

FIG. 1 is a perspective view of a cooler according to embodiment 1. FIG. 2 is a schematic configuration diagram of the cooler according to embodiment 1. FIG. 3 is a cross-sectional view showing a cross section taken along A-A in FIG. 1. In the drawings, a height direction H indicated by an H axis is a direction orthogonal to a plane extending along a main surface S1 of a heat dissipation plate 10 described later, a flow direction F indicated by an F axis is a direction in which a coolant flows inside a case 20 of a cooler 1, and a width direction W indicated by a W axis is a direction orthogonal to the height direction H and the flow direction F.

The cooler 1 cools a heat generation body 2. The heat generation body 2 is, for example, a power conversion device. The cooler 1 can be divided into four portions which are the heat dissipation plate 10, the case 20, a coolant inlet portion 22, and a coolant outlet portion 24.

The case 20 is a member in the form of a box that has the heat dissipation plate 10 having an outer surface on which the heat generation body 2 is provided. The case 20 has an internal space 21 in which a coolant having flowed in from the coolant inlet portion 22 flows. The case 20 is formed from an aluminum material or the like. Although the heat dissipation plate 10 is shown as a member separate from the case 20, the heat dissipation plate 10 is a member forming the case 20.

The coolant inlet portion 22 is a member in the form of a pipe formed from an aluminum material or the like. As shown in FIG. 2, the pipe as a form of the coolant inlet portion 22 has one end connected to an inlet 23 opened in one of surfaces forming the box as a form of the case 20. In addition, a coolant flows in from the other end of the coolant inlet portion 22, whereby the coolant flows into the case 20.

Similar to the coolant inlet portion 22, the coolant outlet portion 24 is also a member in the form of a pipe formed from an aluminum material or the like. As shown in FIG. 2, the pipe as a form of the coolant outlet portion 24 has one end connected to an outlet 25 opened in a surface that is included among the surfaces forming the box as a form of the case 20 and that is opposite to the surface to which the coolant inlet portion 22 is connected. The coolant having flowed through the inside of the case 20 flows to the outside of the case 20 via the outlet 25 and the coolant outlet portion 24. Inside the case 20, the coolant flows from the inlet 23 to the outlet 25.

The heat dissipation plate 10 is a rectangular flat plate formed from a copper material, an aluminum material, or the like. As shown in FIG. 3, the heat generation body 2 is attached to the upper surface, of the heat dissipation plate 10, which is one of the external surfaces (outer surfaces) of the case 20. The lower surface, of the heat dissipation plate 10, which is a surface opposite to the upper surface is referred to as “main surface S1”. The main surface S1 forms one of the internal surfaces (inner surfaces) of the case 20, and the coolant comes into contact with the main surface S1.

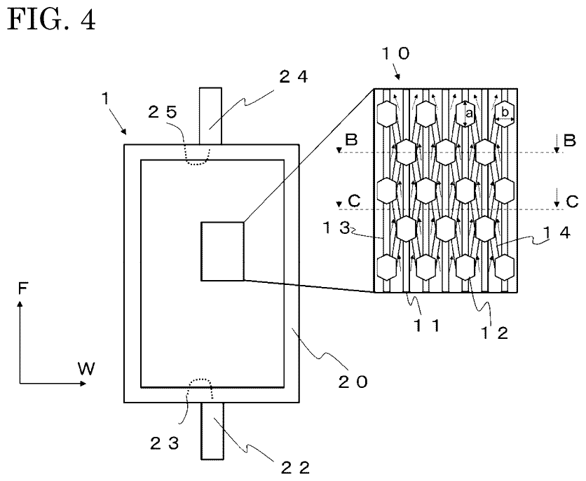

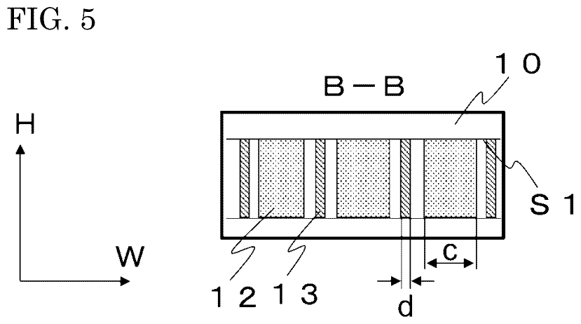

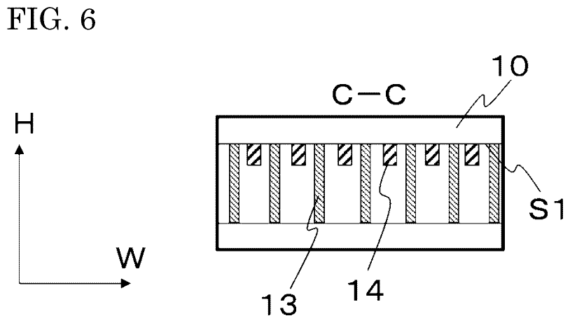

FIG. 4 is a plan view of the main surface S1 of the heat dissipation plate 10 according to embodiment 1 as seen in a direction orthogonal to the main surface S1. FIG. 5 is a cross-sectional view showing a cross section taken along B-B in FIG. 4. FIG. 6 is a cross-sectional view showing a cross section taken along C-C in FIG. 4.

Fins 11 are provided to the heat dissipation plate 10. The fins 11 protrude from the main surface S1 of the heat dissipation plate and form a coolant flow path in the internal space 21 of the case 20. The fins 11 have a plurality of pillar-shaped portions 12, a plurality of plate-shaped portions 13, and a plurality of oblique connection portions 14.

As shown in FIG. 4, the pillar-shaped portions 12 are arranged on the main surface S1 in a staggered pattern as seen in the height direction H. The plurality of pillar-shaped portions 12 are arranged at regular intervals in the flow direction F, in which the coolant flows, so as to form a row. The row is referred to as “fin row”. A plurality of the fin rows are arranged in the width direction W. The fin rows are arranged to be shifted in the width direction W by a unit phase. The fin rows are arrayed such that each of the fin rows is shifted, in the flow direction F, from a fin row adjacent thereto in the width direction W. Consequently, the pillar-shaped portions 12 are arranged on the heat dissipation plate 10 in a staggered pattern.

The shape of each of the pillar-shaped portions 12 is, for example, a hexagonal shape. In the example shown in FIG. 4, the pillar-shaped portion 12 has a surface parallel to the plate-shaped portions 13 described later. In addition, the shape of the pillar-shaped portion 12 is preferably such a shape that a longitudinal width (a) (a width in the flow direction F) of the pillar-shaped portion 12 and a lateral width (b) (a width in the width direction W) of the pillar-shaped portion 12 satisfy a/b>1. That is, the pillar-shaped portion 12 preferably has such a shape that the longitudinal width (a) is larger than the lateral width (b).

The pillar-shaped portion 12 is a solid member formed from aluminum and extends in the height direction H orthogonal to the plane extending along the main surface S1. The height direction H also indicates heights of the case 20 and the fins. As shown in FIG. 5, in the cross section orthogonal to the flow direction F, a length (referred to as “height” below) in the height direction H of the pillar-shaped portion 12 is equal to a distance between the bottom surface of the case 20 and the main surface S1 of the heat dissipation plate 10. That is, the height of the pillar-shaped portion 12 is equal to a height of the coolant flow path.

In addition, as shown in FIG. 4, the plate-shaped portions 13 are provided on the inner surface of the case 20. Each of the plate-shaped portions 13 is orthogonal to the height direction H of the case and mutually connects the corresponding pillar-shaped portions 12 that are adjacent to each other in the flow direction F in which the coolant flows. The plate-shaped portion 13 is a rectangular flat plate formed from an aluminum material. This flat plate is parallel to the height direction H and parallel to the flow direction F.

Each of the plate-shaped portions 13 is provided such that: one end in the flow direction F of the plate-shaped portion 13 is in contact with the corresponding pillar-shaped portion 12 on the inlet 23 side in the flow direction F; and the other end in the flow direction F of the plate-shaped portion 13 is in contact with the corresponding pillar-shaped portion 12 on the outlet 25 side in the flow direction F. That is, each of the plate-shaped portions 13 mutually connects these corresponding pillar-shaped portions 12 adjacent to each other in the flow direction F.

As shown in FIG. 5, heights of the plate-shaped portions 13 are equal to heights of the pillar-shaped portions 12. A length (referred to as “width” below) (d) in the width direction W of each of the plate-shaped portions 13 is smaller than a length (referred to as “width” below) (c) in the width direction W of each of the pillar-shaped portions 12. That is, the width (c) of the pillar-shaped portion 12 and the width (d) of the plate-shaped portion 13 are in such a relationship as to satisfy c/d>1.

In addition, as shown in FIG. 4, the oblique connection portions 14 are provided on the inner surface of the case 20. Each of the oblique connection portions 14 mutually connects the corresponding pillar-shaped portions 12 that are adjacent to each other in a direction obliquely intersecting with the flow direction F of the coolant. The oblique connection portion 14 is tilted relative to the flow direction F and the width direction W. The oblique connection portion 14 mutually connects corner portions of said pillar-shaped portions 12 having polygonal shapes. Here, when the pillar-shaped portions 12 have hexagonal shapes, the corner portion of each of the pillar-shaped portions 12 refers to a corner portion that is included among the six corner portions of the pillar-shaped portion and that is formed by connection between a side surface parallel to the plate-shaped portions 13 and a side surface unparallel to the plate-shaped portions 13. The corner portion includes not only the corresponding corner but also portions of the side surfaces adjacent to the corner. The side surfaces refer to surfaces with which the coolant comes into contact. As shown in FIG. 6, heights of the oblique connection portions 14 are lower than the heights of the pillar-shaped portions 12 and the heights of the plate-shaped portions 13. The oblique connection portions 14 are provided to extend from the heat dissipation plate 10 toward the bottom of the case 20.

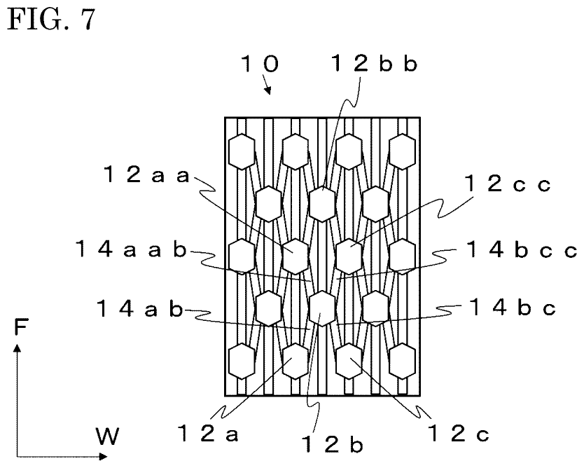

FIG. 7 is a schematic diagram of arrangement of the fins according to embodiment 1. The oblique connection portions 14 will be described in more detail with reference to FIG. 7. The coolant is assumed to flow from the lower side on the drawing sheet of FIG. 7 toward the upper side on said drawing sheet.

As shown in FIG. 7, a plurality of pillar-shaped portions 12 forming one arbitrarily-selected fin row among the fin rows sequentially arranged in the width direction W are defined as pillar-shaped portions 12a and 12aa in this order in the flow direction F. In addition, a plurality of pillar-shaped portions 12 forming a fin row adjacent, in the width direction W, to the fin row including the pillar-shaped portions 12a and 12aa are defined as pillar-shaped portions 12b and 12bb in this order in the flow direction F. Furthermore, a plurality of pillar-shaped portions 12 forming a fin row adjacent, in the width direction W, to the fin row including the pillar-shaped portions 12b and 12bb are defined as pillar-shaped portions 12c and 12cc in this order in the flow direction F.

The pillar-shaped portion 12b and the pillar-shaped portion 12aa adjacent thereto in an oblique direction obliquely intersecting with the flow direction F are connected by an oblique connection portion 14aab. The pillar-shaped portion 12b and the pillar-shaped portion 12cc adjacent thereto in an oblique direction obliquely intersecting with the flow direction F are connected by an oblique connection portion 14bcc. That is, the pillar-shaped portion 12b is connected by the oblique connection portion 14aab to the pillar-shaped portion 12aa on the downstream side and on an oblique front side and is connected by the oblique connection portion 14aab to the pillar-shaped portion 12cc on the downstream side and on an oblique front side.

In addition, the pillar-shaped portion 12b is connected by an oblique connection portion 14ab to the pillar-shaped portion 12a which is on the upstream side relative to the pillar-shaped portion 12b and which is located rearward of the pillar-shaped portion 12b in a direction tilted from the flow direction F. The pillar-shaped portion 12b is connected by an oblique connection portion 14bc to the pillar-shaped portion 12c which is on the upstream side relative to the pillar-shaped portion 12b and which is located rearward of the pillar-shaped portion 12b in a direction tilted from the flow direction F. That is, the pillar-shaped portions 12 connected by each of the oblique connection portions 14 are closest to each other in the fin rows adjacent to each other in the width direction W.

A distance of each of the oblique connection portions 14 (a distance between the corresponding pillar-shaped portions 12 that are closest to each other in the fin rows adjacent to each other in the width direction W) is longer than a distance between each of said pillar-shaped portions 12 and a plate-shaped portion 13 adjacent to the pillar-shaped portion 12 in the width direction W. That is, a length of each of the oblique connection portions 14 is longer than a distance between each of the corresponding pillar-shaped portions 12 and a plate-shaped portion 13 closest to the pillar-shaped portion 12 among the plate-shaped portions 13.

Next, the flow of a coolant in the cooler 1 according to the present embodiment will be described. A coolant is supplied from the coolant inlet portion 22 and flows into the internal space 21 of the case from the inlet 23. The coolant having flowed in flows toward the outlet 25 through the coolant flow path formed by the pillar-shaped portions 12, the plate-shaped portions 13, the oblique connection portions 14, the main surface S1 of the heat dissipation plate 10, and the inner surfaces of the case 20. In the coolant flow path, the coolant comes into contact with the fins 11 and the main surface S1 of the heat dissipation plate 10, to cool the heat generation body 2. The coolant having reached the outlet 25 flows to the outside of the case 20 from the coolant outlet portion 24.

The cooler 1 is provided to, for example, a coolant circulation passage of a cooling system 30 described later. In this case, the other end of the coolant inlet portion 22 is connected to piping 60, and a coolant having passed through the piping 60 flows into the case 20. The other end of the coolant outlet portion 24 is connected to the piping 60. Consequently, the coolant having passed through the case 20 flows out from the coolant outlet portion 24 to piping 70.

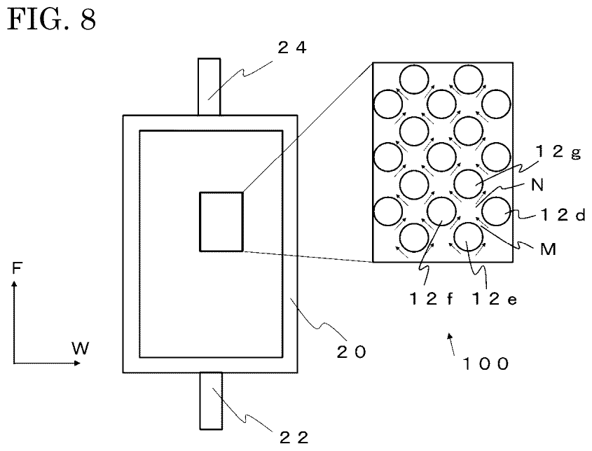

Here, cooling to be performed when a plurality of pin fins having columnar shapes are arranged on a heat dissipation plate will be described as a comparative example. FIG. 8 is a plan view of a heat dissipation plate 100 to be compared with the heat dissipation plate in embodiment 1.

Under the heat dissipation plate 100, a coolant having collided with a pin fin 12d passes through: a gap M between the pin fin 12d and a pin fin 12e located on the upstream side relative to the pin fin 12d; and a gap N between the pin fin 12d and a pin fin 12f adjacent to the pin fin 12d in the width direction W orthogonal to the flow direction F. Then, the coolant collides with a pin fin 12g located on the downstream side relative to the pin fin 12d. At this time, since the gap N is wider than the gap M, the flow rate of the coolant is decreased at the gap N. As a result, the cooling efficiency near the gap N deteriorates. In addition, the coolant does not easily flow near corner portions of the pin fins (in particular, on the rear sides (upstream sides) relative to the corner portions) owing to influence of peeling, whereby the cooling efficiency near the corner portions deteriorates.

Meanwhile, the cooler 1 according to the present embodiment 1 is a cooler for cooling a heat generation body 2, the cooler 1 including: a case 20 having an outer surface on which the heat generation body 2 is provided, the case 20 having an internal space 21 in which a coolant flows; and fins 11 protruding from an inner surface (main surface S1) of the case and forming a coolant flow path in the internal space 21. The fins 11 have: a plurality of pillar-shaped portions 12 arranged in a staggered pattern; a plurality of plate-shaped portions 13 each of which is orthogonal to a height direction H of the case and mutually connects the corresponding pillar-shaped portions 12 that are adjacent to each other in a flow direction F in which the coolant flows; and a plurality of oblique connection portions 14 each of which mutually connects the corresponding pillar-shaped portions 12 that are adjacent to each other in an oblique direction obliquely intersecting with the flow direction F.

Since the cooler 1 according to the present embodiment 1 has this configuration, the cooler 1 can efficiently cool heat generated from the heat generation body 2.

Specifically, each of the plate-shaped portions 13 is located at the center in the width direction W of the corresponding gap N. Consequently, a width of the flow path at the gap N is smaller than that obtained when no plate-shaped portion 13 is present. As a result, decrease in the flow rate of the coolant at the gap N is suppressed, and deterioration of the cooling efficiency is suppressed.

Therefore, decrease in heat transfer coefficient due to a distribution of flow rates can be suppressed, whereby the cooler 1 can efficiently cool heat generated from the heat generation body 2.

In addition, since the oblique connection portions 14 are provided, formation of a turbulent flow of the coolant is facilitated, whereby cooling can be more efficiently performed. Each of the oblique connection portions 14 connects pillar-shaped portions 12 that are adjacent to each other in an oblique direction relative to the flow direction F of the coolant among the plurality of pillar-shaped portions 12 arranged in a staggered pattern. That is, since the oblique connection portion 14 is provided near the corner portions, of the pillar-shaped portions 12, that easily peel, the coolant is stirred by colliding with the oblique connection portion 14, whereby formation of a turbulent flow of the coolant is facilitated. The formation of the turbulent flow enables suppression of stagnation (generation of a deadwater region) of the coolant due to peeling, whereby the distribution of the flow rates between the fins can be decreased. In addition, the formation of the turbulent flow enables suppression of generation of a deadwater region near the corner portions of the pillar-shaped portions 12, whereby the surface areas of the pillar-shaped portions 12 can be effectively utilized. With the above features, decrease in heat transfer coefficient can be suppressed, and the heat generation body 2 can be efficiently cooled. In addition, since the coolant obliquely collides with the oblique connection portion 14, pressure loss can also be decreased.

In addition, since the main surface S1 of the heat dissipation plate 10 (the inner surface of the case 20) is provided with the plate-shaped portions 13 and the oblique connection portions 14, the surface area of contact with the coolant is larger than under a heat dissipation plate provided with neither the plate-shaped portions 13 nor the oblique connection portions 14. Therefore, the cooler 1 including the heat dissipation plate 10 has a higher ability to cool the heat generation body 2 than a conventional cooler including the heat dissipation plate 100 provided with neither the plate-shaped portions 13 nor the oblique connection portions 14. Furthermore, since the pillar-shaped portions 12, the plate-shaped portions 13, and the oblique connection portions 14 are connected, the earthquake-resistance strength is also improved, and a vibration-suppressing effect can also be expected to be obtained.

In addition, the length of each of the oblique connection portions 14 is longer than the distance between each of the corresponding pillar-shaped portions 12 and a plate-shaped portion 13 closest to the pillar-shaped portion 12 among the plate-shaped portions 13. Each of the oblique connection portions 14, instead of connecting a pillar-shaped portion 12 and a plate-shaped portion 13 adjacent thereto in the width direction W, mutually connects pillar-shaped portions 12 that are closest to each other in the fin rows adjacent to each other in the width direction W, and thus the area of contact with the coolant is increased, whereby the cooling performance is improved.

In addition, the pillar-shaped portions 12 are arranged on the main surface S1 of the heat dissipation plate 10 in a staggered pattern as seen in the height direction H. Consequently, the coolant flowing inside the cooler 1 collides with the pillar-shaped portions 12 in a direction parallel to the flow direction F, and development of a thermal boundary layer around each of the pillar-shaped portions 12 is suppressed owing to a leading-edge effect. As a result, the cooler 1 can efficiently cool heat generated from the heat generation body 2.

Furthermore, the pillar-shaped portions 12 have hexagonal shapes. Here, a case where the pillar-shaped portions 12 have columnar shapes is assumed. In this case, the flow of the coolant is less likely to become turbulent near the surfaces of the pillar-shaped portions 12.

Meanwhile, when the pillar-shaped portions 12 have hexagonal shapes as in the present embodiment 1, turbulence of a flow (formation of a turbulent flow) of the coolant can be facilitated. Furthermore, the longitudinal width (a) of each of the pillar-shaped portions 12 and the lateral width (b) of the pillar-shaped portion 12 satisfy a/b>1, whereby the area of contact between the coolant and the pillar-shaped portion 12 can be increased, and the cooling performance is improved.

The heights of the pillar-shaped portions 12 and the heights of the plate-shaped portions 13 are equal to the height of the coolant flow path. Thus, the surface areas of the fins 11 in contact with the coolant are increased, whereby the heat generation body 2 can be more efficiently cooled.

The heights of the oblique connection portions 14 are set to be lower than the heights of the pillar-shaped portions 12 and the heights of the plate-shaped portions 13. With this configuration, the area of contact between the heat dissipation plate 10 and the coolant can be increased, and furthermore, formation of a turbulent flow of the coolant can be facilitated. Therefore, the heat generation body 2 can be more efficiently cooled.

In addition, the width (d) of each of the plate-shaped portions 13 is smaller than the width (c) of each of the pillar-shaped portions 12. That is, the relationship expressed as c/d>1 is established. With this configuration, the area of contact between the coolant and each of the pillar-shaped portion 12 and the plate-shaped portion 13 can be increased, and the leading-edge effect of the pillar-shaped portion 12 can be increased, whereby the heat generation body 2 can be more efficiently cooled.

In addition to this feature, for the heat dissipation plate 10 of the cooler 1, aluminum is used as a material of the pillar-shaped portion 12, and copper is used as a material of the plate-shaped portion 13. For example, when a thickness of the flat plate as a form of the plate-shaped portion 13 is smaller than a width of the hexagon as a shape of the pillar-shaped portion 12, the cooling performance of the plate-shaped portion 13 might become poorer than that of the pillar-shaped portion 12. However, deterioration of the cooling performance of the plate-shaped portion 13 can be suppressed by using, as a material of the plate-shaped portion 13, copper having a higher thermal conductivity than aluminum. When the material of the pillar-shaped portions 12 and the material of the plate-shaped portions 13 differ from each other, examples of the manufacturing methods for the pillar-shaped portions 12 and the plate-shaped portions 13 include: a method that includes forming the pillar-shaped portions 12 on the heat dissipation plate 10 and then press-fitting the plate-shaped portions 13; and a method that includes adhering the plate-shaped portions 13 to the pillar-shaped portions 12 through brazing or the like.

Although the heights of the pillar-shaped portions 12 and the plate-shaped portions 13 are set to be equal to the height of the coolant flow path, said heights may be set to be shorter than the height of the coolant flow path according to the extent of warping of the heat dissipation plate 10 as long as said heights are higher than the heights of the oblique connection portions 14.

A power conversion device as an example of the heat generation body 2 is a converter, an inverter, or a regulator for controlling a motor 80 described later and includes semiconductor elements such as MOSFETs or IGBTs, a reactor, a capacitor, and the like. The semiconductor elements and the like included in the power conversion device are mounted on an insulating substrate inside the power conversion device.

At the time of operation of the motor 80, current flows through the power conversion device in order to control the motor 80, whereby the temperatures of the semiconductor elements and the like included in the power conversion device become high.

### Embodiment 2

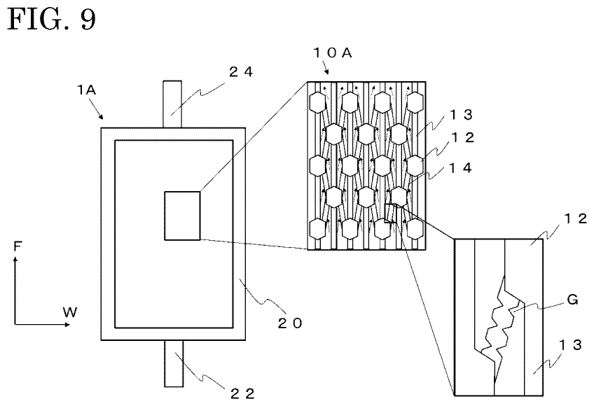

A cooler 1A according to embodiment 2 will be described with reference to FIG. 9. The cooler 1A according to embodiment 2 differs from the cooler 1 according to embodiment 1 in terms of the shapes of the oblique connection portions 14. Description of the same configurations as those in embodiment 1 is omitted, and the same or corresponding portions as those in embodiment 1 are denoted by the same reference characters.

FIG. 9 is a plan view of the main surface S1 of a heat dissipation plate 10A of the cooler 1A according to embodiment 2 as seen in a direction orthogonal to this surface.

Under the heat dissipation plate 10A of the cooler 1A according to embodiment 2, a plurality of recess-projection portions G are formed in side surfaces (i.e., surfaces with which the coolant comes into contact) of each of the oblique connection portions 14. Each of the recess-projection portions G has a V-shaped cross section and is a groove extending in the height direction H. Consequently, the area of contact with the coolant under the heat dissipation plate 10A is larger than that under the heat dissipation plate 10. As a result, the cooler 1A not only exhibits the advantageous effects in embodiment 1 but also can further efficiently cool heat generated from the heat generation body 2. The other configurations in the cooler 1A are the same as those in the cooler 1.

### Embodiment 3

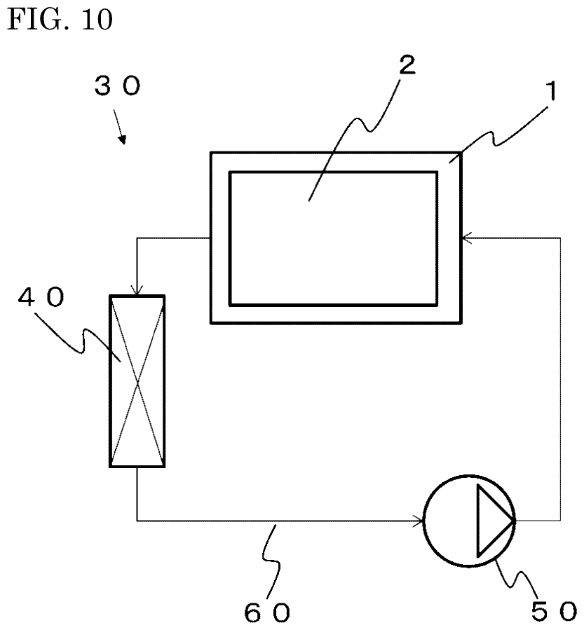

A cooling system 30 according to embodiment 3 will be described with reference to FIG. 10. The cooling system 30 according to embodiment 3 is a cooling system 30 including the cooler described in embodiment 1 or 2. Description of the same configurations as those in embodiment 1 is omitted, and the same or corresponding portions as those in embodiment 1 are denoted by the same reference characters.

FIG. 10 is a configuration diagram showing a configuration of the cooling system 30 according to embodiment 3. The cooling system 30 includes: the cooler 1 or 1A described in embodiment 1 or 2; a heat exchanger 40; a pump 50; and piping 60 connecting these constituents.

The cooling system 30 is a cooling circuit for cooling the heat generation body 2 by using a coolant. In the present embodiment 3, the heat generation body 2 is the power conversion device.

A coolant flowing through the cooling system 30 circulates in the cooling circuit in the order of the heat exchanger 40, the pump 50, and the cooler 1 provided with the heat generation body 2. The cooler 1 (1A), the heat exchanger 40, and the pump are connected by the piping 60. Thus, in the cooling circuit, the coolant cooled by the heat exchanger 40 is sent to the cooler 1 (1A) by the pump 50. By causing the coolant to flow into the cooler 1 and performing heat exchange, the heat generation body 2 is cooled. The coolant having received heat flows into the heat exchanger 40 again and is cooled by the heat exchanger 40.

The coolant flowing through the cooling circuit is an antifreeze (LLC) obtained by mixing, with an ethylene glycol aqueous solution, an additive that functions as a rust inhibitor, a preservative, or a defoamer.

As described above, the cooling system 30 according to the present embodiment is a cooling circuit through which a coolant flows, the cooling system 30 including: the cooler 1 (1A) described in embodiment 1 or 2; a heat exchanger 40 which cools the coolant; a pump 50 which sends the coolant to the cooler 1 (1A); and piping 60 connecting the cooler 1 (1A), the heat exchanger 40, and the pump 50. Consequently, the heat generation body 2 can be efficiently cooled.

The above embodiments may be combined, modified, or simplified as appropriate within the scope of technical ideas described in the embodiments. For example, although the coolant in the above embodiments is an antifreeze, the antifreeze may be substituted with cooled gas. Also, not only the V-shaped grooves, but also semi-circular recesses or the like, may be provided as the recess-projection portions G formed in the side surfaces of each of the oblique connection portions 14.

### DESCRIPTION OF THE REFERENCE CHARACTERS

1, 1A cooler
2 heat generation body (power conversion device)
10, 10A heat dissipation plate
11 fin
12, 12a, 12aa, 12b, 12bb, 12c, 12cc pillar-shaped portion
13 plate-shaped portion
14, 14aab, 14bcc, 14ab, 14bc oblique connection portion
20 case
21 internal space
22 coolant inlet portion
23 inlet
24 coolant outlet portion
25 outlet
30 cooling system
40 heat exchanger
50 pump
60 piping
100 heat dissipation plate
F flow direction
G recess-projection portion
H height direction
S1 main surface
W width direction

1. A cooler for cooling a heat generation body, the cooler comprising:
a case having an outer surface on which the heat generation body is provided, the case having an internal space in which a coolant flows; and
fins protruding from an inner surface of the case and forming a coolant flow path in the internal space, wherein
the fins have
a plurality of pillar-shaped portions arranged in a staggered pattern,
a plurality of plate-shaped portions each of which is orthogonal to a height direction of the case and mutually connects the corresponding pillar-shaped portions that are adjacent to each other in a flow direction in which the coolant flows, and
a plurality of oblique connection portions each of which mutually connects the corresponding pillar-shaped portions that are adjacent to each other in an oblique direction obliquely intersecting with the flow direction.

2. The cooler according to claim 1, wherein
the plurality of pillar-shaped portions are arranged at intervals in the flow direction so as to form a fin row, and
a plurality of the fin rows are arranged at intervals in a width direction orthogonal to the height direction and the flow direction and are arrayed such that each of the fin rows is shifted, in the flow direction, from a fin row adjacent thereto in the width direction.

3. The cooler according to claim 2, wherein the pillar-shaped portions mutually connected by each of the oblique connection portions are closest to each other among the pillar-shaped portions forming the fin rows adjacent to each other in the width direction.

4. The cooler according to claim 1, wherein heights of the pillar-shaped portions and heights of the plate-shaped portions are equal to a height of the coolant flow path.

5. The cooler according to claim 1, wherein heights of the oblique connection portions are lower than heights of the pillar-shaped portions and heights of the plate-shaped portions.

6. The cooler according to claim 1, wherein
the pillar-shaped portions have polygonal shapes, and
each of the oblique connection portions mutually connects corner portions of the corresponding pillar-shaped portions.

7. The cooler according to claim 1, wherein a length of each of the oblique connection portions is longer than a distance between each of the corresponding pillar-shaped portions and a plate-shaped portion closest to the pillar-shaped portion among the plate-shaped portions.

8. The cooler according to claim 1, wherein a shape of each of the pillar-shaped portions is such a shape that a longitudinal width (a) in the flow direction of the pillar-shaped portion and a lateral width (b), in a width direction orthogonal to the flow direction, of the pillar-shaped portion are in such a relationship as to satisfy a/b>1.

9. The cooler according to claim 1, wherein, in a cross section perpendicular to the flow direction, a width (c) of each of the pillar-shaped portions and a width (d) of each of the plate-shaped portions are in such a relationship as to satisfy c/d>1.

10. The cooler according to claim 1, wherein each of the oblique connection portions has, in a side surface thereof, a recess-projection portion.

11. A cooling system as a cooling circuit through which the coolant flows, the cooling system comprising:
the cooler according to claim 1;
a heat exchanger which cools the coolant;
a pump which sends the coolant to the cooler; and
piping connecting the cooler, the heat exchanger, and the pump.
